(19) United States
(12) Patent Application Publication
(10) Pub. No.: US 2025/0308979 A1
(43) Pub. Date: Oct. 2, 2025

(54) SHAFT MEMBERS, SHAFT ARRANGEMENTS AND SEMICONDUCTOR PROCESSING SYSTEMS INCLUDING SHAFT MEMBERS, AND RELATED METHODS OF MAKING SHAFT MEMBERS FOR SHAFT ARRANGEMENTS

(71) Applicant: ASM IP Holding B.V., Almere (NL)

(72) Inventor: Bradley Wayne Evans, Apache Junction, AZ (US)

(21) Appl. No.: 19/092,207

(22) Filed: Mar. 27, 2025

Related U.S. Application Data
(60) Provisional application No. 63/571,797, filed on Mar. 29, 2024.

(51) Int. Cl. H01L 21/687; C30B 25/12

(52) U.S. Cl. CPC H01L 21/68792; C30B 25/12

(57) ABSTRACT

A shaft member includes a shaft member body arranged along an axis having a drive end, an intermediate segment, and a seat end. The drive end defines a fixation feature therein, the intermediate segment extends from the drive end of the shaft member body, and the seat end is axially separated from the drive end of the shaft member body by the intermediate segment of the shaft member body. The seat end has one or more oblique facet to axially locate a spider member on the shaft member body. Shaft arrangements, semiconductor processing systems, and methods of making shaft members are also described.

### CROSS-REFERENCE TO RELATED APPLICATIONS

This application claims priority to and the benefits of U.S. Provisional Patent Application Ser. No. 63/571,797, filed Mar. 29, 2024 and titled SHAFT MEMBERS, SHAFT ARRANGEMENTS AND SEMICONDUCTOR PROCESSING SYSTEMS INCLUDING SHAFT MEMBERS, AND RELATED METHODS OF MAKING SHAFT MEMBERS FOR SHAFT ARRANGEMENTS, the contents of which is hereby incorporated by reference in its entirety.

### FIELD OF INVENTION

The present disclosure generally transmitting power in mechanical systems, and more particular to limiting backlash in mechanisms systems employed for power transmission.

### BACKGROUND OF THE DISCLOSURE

Mechanical systems are commonly employed transmit power, such as rotation or force, using structures like shafts and push rods. Shafts are generally supported for rotational movement using bearings or bushings and typically transmit rotation to a rotated structure through a coupling. Push rods are generally supported for directional movement, typically using a guide or sleeve, and may be similarly coupled to a pushed or pulled structure through a coupling. In some mechanical systems, gaps may exist between various elements within the mechanical system. Such gaps can cause clearances or lost motion within the mechanism, potentially requiring that parts be oversized in relation to a size otherwise desired for the application and/or requiring that movement of structures be slowed relative to an otherwise desired motion to accommodate the backlash. While generally acceptable for its intended purpose, oversizing and/or slowing mechanical elements in mechanical systems can limit performance of the mechanical systems.

Such systems and methods have generally been acceptable for their intended purpose. However, there remains a need for improved shaft members, shaft arrangements and semiconductor processing systems including shaft members, and methods of making shafts and shaft arrangements for semiconductor processing systems. The present disclosure provides a solution to this need.

### SUMMARY OF THE DISCLOSURE

A shaft member is provided. A shaft member includes a shaft member body arranged along an axis having a drive end, an intermediate segment, and a seat end. The drive end defines a fixation feature therein, the intermediate segment extends from the drive end of the shaft member body, and the seat end is axially separated from the drive end of the shaft member body by the intermediate segment of the shaft member body. The seat end has one or more oblique facet to axially locate a spider member on the shaft member body.

In addition to one or more of the features described above, or as an alternative, further examples of the shaft member may include that the shaft member body is formed from a transparent material, such as a ceramic material like quartz.

In addition to one or more of the features described above, or as an alternative, further examples of the shaft member may include the shaft member has a seat end face axially opposite the drive end of the shaft member body that is substantially orthogonal to the axis.

In addition to one or more of the features described above, or as an alternative, further examples of the shaft member may include that the shaft member defines therein a through-bore. The through-bore may extend axially from a seat end face aperture defined within the seat end face of shaft member body to the drive end of the shaft member body.

In addition to one or more of the features described above, or as an alternative, further examples of the shaft member may include that the seat end of the shaft member body defines an oblique facet-to-seat end face chamfer. The oblique facet-to-seat end face chamfer may couple the one or more oblique facet to the seat end face of the shaft member body.

In addition to one or more of the features described above, or as an alternative, further examples of the shaft member may include that the oblique facet is angled relative to the axis at an oblique facet angle that is between about 5 degrees and about 40 degrees, or between about 5 degrees and about 30 degrees, or between about 5 degrees and about 25 degrees, or between about 10 degrees and about 20 degrees. The oblique facet may be angled relative to the axis at an oblique facet angle that is between about 5 degrees and about 15 degrees, or that is between about 8 degrees and about 12 degrees, or is about 10 degrees in certain examples.

In addition to one or more of the features described above, or as an alternative, further examples of the shaft member may include that the one or more oblique facet is one of three (3) oblique facets defined on the seat end of the shaft member body.

In addition to one or more of the features described above, or as an alternative, further examples of the shaft member may include that the seat end of the shaft member body defines one or more wedge facet circumferentially offset from the one or more oblique facet about the rotation axis.

In addition to one or more of the features described above, or as an alternative, further examples of the shaft member may include that the one more wedge facet is substantially parallel to the intermediate segment of the shaft member body.

In addition to one or more of the features described above, or as an alternative, further examples of the shaft member may include that the one or more wedge facet is one of three (3) wedge facets defined by the seat end of the shaft member body, that the one or more oblique facet is one of three (3) oblique facets defined by the seat end of the shaft member body, and that each of the wedge facets separate circumferentially adjacent circumferentially adjacent oblique facets of the seat end of the shaft member body.

In addition to one or more of the features described above, or as an alternative, further examples of the shaft member may include that the seat end of the shaft member body defines a wedge facet-to-oblique facet chamfer. The wedge facet-to-oblique facet chamber may couple the one or more wedge facet to the one or more oblique facet.

In addition to one or more of the features described above, or as an alternative, further examples of the shaft member may include that the one or more wedge portion defines a wedge facet-to-seat end face chamfer. The wedge facet-to-seta end face chamfer may couple the one or more wedge facet to the seat end face of the seat end of the shaft member body.

A shaft arrangement is provided. The shaft arrangement includes a shaft member as described above and spider member. The shaft member body of the shaft member defines one or more wedge portion circumferentially offset from the one or more oblique facet. The spider member includes a spider member body having a hub portion extending about the axis and defining a seating socket therein, one or more arm portion extending radially from the hub portion, and one or more seat portion extending axially from the arm portion and radially separated from the hub portion by the arm portion of the spider member body. The shaft end of the spider member body is received within the seating socket defined within the hub portion of the spider member body.

In addition to one or more of the features described above, or as an alternative, further examples of the shaft arrangement may include that the seating socket is bounded by one or more oblique face. The one or more oblique face may be conjugate to the one or more oblique facet defined by the seat end of the shaft member body.

In addition to one or more of the features described above, or as an alternative, further examples of the shaft arrangement may include that the seating socket is bounded by three (3) oblique faces distributed circumferentially about the rotation axis. Each of the three (3) oblique facets may be conjugate to a respective one (1) of three (3) oblique facets defined by the seat end of the shaft member body.

In addition to one or more of the features described above, or as an alternative, further examples of the shaft arrangement may include that the seating socket is bounded by one or more wedge face. The one or more wedge face may be conjugate to the one or more wedge facet defined by the seat end of the shaft member body.

In addition to one or more of the features described above, or as an alternative, further examples of the shaft arrangement may include that the seating socket is bounded by three (3) wedge faces distributed circumferentially about the rotation axis. Each of the three (3) wedge facets may be conjugate to a respective one (1) of three (3) wedge facets defined by the seat end of the shaft member body.

In addition to one or more of the features described above, or as an alternative, further examples of the shaft arrangement may include the hub portion has an upper surface defining an upper aperture and a lower surface defining lower aperture. The lower aperture may be coupled to the upper aperture by the seating socket. The lower aperture may have a generally circular shape. The upper aperture may be bounded by a plurality linear segments and linear segments.

In addition to one or more of the features described above, or as an alternative, further examples of the shaft arrangement may include that the one or more oblique face defines a relief recess therein. The relief recess defined within the oblique face may extend from the upper aperture to a location axially intermediate the upper aperture and the lower aperture of the hub portion of the spider member body.

In addition to one or more of the features described above, or as an alternative, further examples of the shaft arrangement may include a tube member and a lift pin actuator. The tube member may be arranged along the rotation axis and extend circumferentially about the shaft member. The lift pin actuator may be seated on the tube member and extend circumferentially about the shaft member and axially separated from the tube member by the lift pin actuator.

In addition to one or more of the features described above, or as an alternative, further examples of the shaft arrangement may include a substrate support seated on the spider member and coupled therethrough to the shaft member.

In addition to one or more of the features described above, or as an alternative, further examples of the shaft arrangement may include that one or more of the spider member, the tube member, and the lift pin actuator may be formed from a transparent material, such as a ceramic material like quartz.

A semiconductor processing system is provided. The semiconductor processing system includes a process fluid source including a material layer precursor, a chamber arrangement including a shaft member as described above coupling a substrate support to a lift and rotate module, an exhaust source coupled to the chamber arrangement, and a controller operatively coupled to the chamber arrangement. The semiconductor processing system may be configured to deposit a material layer onto a substrate seated on the substrate support using a flow of the material layer precursor communicated by the process fluid source, such as a silicon-containing material layer epitaxial with an underlying substrate.

A method of making a shaft arrangement is provided. The method includes arranging a shaft member body formed from a ceramic material along an axis, defining a fixation feature on a drive end of the shaft member body, defining an intermediate segment extending axially from the drive end of the shaft member body, and defining a seat end axially separated from the drive end of the shaft member body by grinding one or more oblique facet into the shaft member body configured to axially locate a spider member on the shaft member body in a 3-2-1 locating scheme.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic view of a shaft arrangement including a shaft member in accordance with an example of the present disclosure, showing the shaft member supporting a substrate support within a chamber arrangement of a semiconductor processing system;

FIG. 2 is a schematic view of a portion of the semiconductor processing system of FIG. 1 according to an example of the present disclosure, showing a precursor source providing a process fluid the semiconductor processing system to deposit a material layer onto a substrate seated on the substrate support;

FIG. 3 is schematic view of a portion of the semiconductor processing system of FIG. 1 according to an example of the disclosure, showing the arrangement and the shaft member arranged within a chamber arrangement having a single-wafer crossflow architecture;

FIG. 4 is side elevation view of the shaft arrangement of FIG. 1 according to an example of the disclosure, showing a spider member seated on the shaft member and a lift pin actuator seated on a tube member;

FIG. 5 is an exploded view of the shaft arrangement of FIG. 1 according to an example of the disclosure, showing the spider member exploded away from the shaft member and the lift pin actuator exploded away from the tube member;

FIGS. 6-8 are side elevation and perspective views of the shaft member of FIG. 1 according to an example of the disclosure, showing wedge facets and oblique facets defined on a seat end of the shaft member to seat the spider member on the seat end of the shaft member;

FIGS. 9 and 10 are a top plan and cross-sectional views of the shaft member of FIG. 1 according to an example of the disclosure, showing the facets and a through-bore, respectively;

FIG. 11 is a plan view of a spider member of the shaft arrangement of FIG. 1 according to an example of the disclosure, showing respective seat portions of the spider member connected to a hub portion by arm portions of the spider member;

FIG. 12 is a cross-sectional side view of the spider member of FIG. 1 according to an example the disclosure, showing a seating socket having oblique faces and wedge slots defined within the hub portion of the spider member body;

FIG. 13 is a plan view of a portion of the hub portion of the spider member of FIG. 1 according to an example of the present disclosure, showing an upper aperture bounded by linear and arcuate segments according to an example of the present disclosure;

FIG. 14 is a cross-sectional side view of the hub portion of the spider member of FIG. 1 according to an example of the present disclosure, showing a wedge face and a circumferentially opposite oblique face defined within the seating socket of the spider member;

FIG. 15 is another cross-sectional side view of the hub portion of the spider member of FIG. 1 according to an example of the present disclosure, showing the wedge face with a relief slot defined therein according to an example of the present disclosure; and

FIG. 16 is a block diagram of a method of making a shaft arrangement, showing operations of the method according to an illustrative and non-limiting example of the method.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

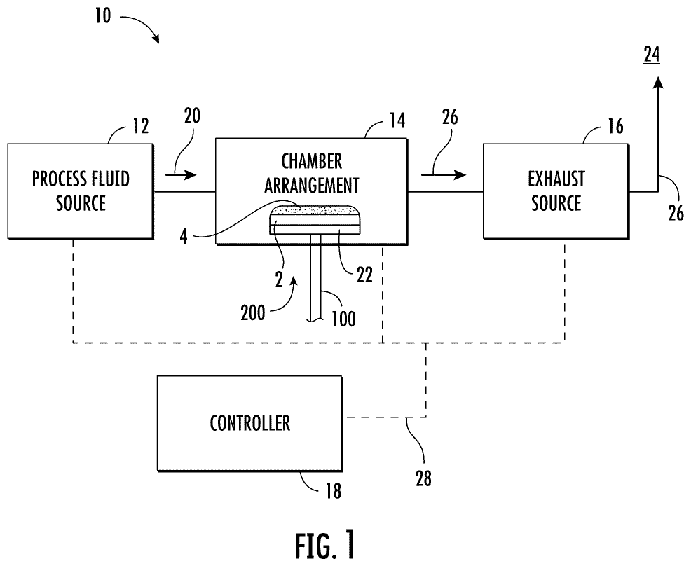

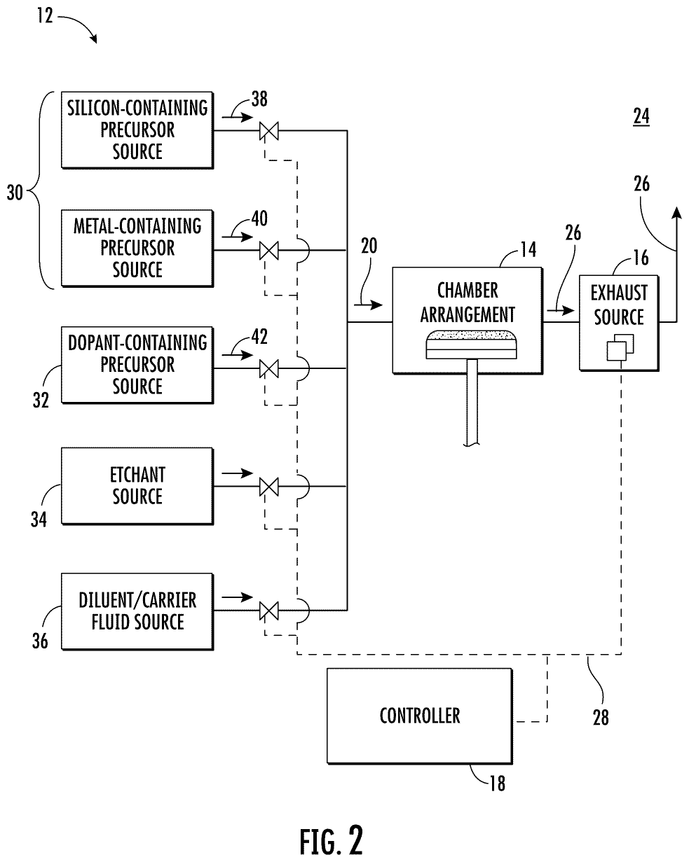

Reference will now be made to the drawings wherein like reference numerals identify similar structural features or aspects of the subject disclosure. For purposes of explanation and illustration, and not limitation, a partial view of an example of a shaft member in accordance with the present disclosure is shown in FIG. 1 and is designated generally by reference character 200. Other examples of shaft members, shaft arrangements and semiconductor processing systems including shaft members, and methods of making shaft members and shaft arrangements in accordance with the present disclosure, or aspects thereof, are provided in FIGS. 2-16, as will be described. The systems and methods of the present disclosure may be used to transmit rotation in rotating machinery, such as in semiconductor processing systems employing rotating substrate supports during the deposition of epitaxial silicon-containing material layers onto substrates seated on the substrate support, though the present disclosure is not limited material layer deposition or to semiconductor processing systems in general.

Referring to FIG. 1, a semiconductor processing system 10 including a shaft arrangement 100 with the shaft member 200 is shown. The semiconductor processing system 10 generally includes a process fluid source 12, a chamber arrangement 14, an exhaust source 16, and a controller 18. The process fluid source 12 is configured to communicate a process fluid 20 to the chamber arrangement 14. The chamber arrangement 14 couples the process fluid source 12 to the exhaust source 16 and includes a substrate support 22, e.g., a susceptor, configured and adapted to support a substrate 2 during deposition of a material layer 4 onto the substrate 2. The chamber arrangement 14 further includes the shaft arrangement 100 with the shaft member 200, which is coupled to the substrate support 22. It is contemplated that the exhaust source 16 be in communication with an external environment 24 outside of the semiconductor processing system 10, be configured to communicate residual precursor and/or reaction products 26 issued by the chamber arrangement 14, and may include one or more of a vacuum and an abatement apparatus, such as scrubber and/or a burn box. It is also contemplated that the controller 18 be operatively coupled to the chamber arrangement 14, for example through a wired or wireless link 28.

As used herein the term “substrate” may refer to any underlying material or materials, including any underlying material or materials that may be modified, or upon which, a device, a circuit, or a film may be formed. A substrate may be continuous or non-continuous; rigid or flexible; solid or porous; and combinations thereof. A substrate may be in any form such as (but not limited to) a powder, a plate, or a workpiece. A substrate in the form of a plate may include a wafer in various shapes and sizes, for example, including 300-millimeter wafers. A substrate may be formed from semiconductor materials, including, for example, silicon (Si), silicon-germanium (SiGe), silicon oxide (SiO₂), gallium arsenide (GaAs), gallium nitride (GaN) and silicon carbide (SiC). A substrate may include a pattern or may be unpatterned, such as a so-called blanket-type substrate. As examples, substrates in the form of a powder may have applications for pharmaceutical manufacturing.

A porous substrate may including one or more polymers. Examples of workpieces may include medical devices (for example, stents and syringes), jewelry, tooling devices, components for battery manufacturing (for example, anodes, cathodes, or separators) or components of photovoltaic cells, etc. A continuous substrate may extend beyond the bounds of a process chamber where a deposition process occurs. In some processes, a continuous substrate may move through the process chamber such that the process continues until the end of the substrate is reached. A continuous substrate may be supplied from a continuous substrate feeding system to allow for manufacture and output of the continuous substrate in any appropriate form. Non-limiting examples of continuous substrates may include sheets, non-woven films, rolls, foils, webs, flexible materials, bundles of continuous filaments or fibers (for example, ceramic fibers or polymer fibers). A continuous substrate may also comprise a carrier or sheet upon which one or more non-continuous substrate is mounted.

With reference to FIG. 2, the process fluid source 12 and the exhaust source 16 are shown according to an example of the present disclosure. In the illustrated example the process fluid source 12 includes one or more material layer precursor source 30, a dopant-containing material layer precursor source 32, an etchant source 34, and a carrier/diluent fluid source 36. The one or more material layer precursor source 30 includes a silicon-containing material layer precursor 38, is coupled the chamber arrangement 14, and is configured to communicate a flow of the silicon-containing material layer precursor 38 to the chamber arrangement 14. It is contemplated that the one or more material layer precursor source 30 may be coupled to the chamber arrangement 14 via one or more mass flow control device, e.g., a mass flow controller (MFC) device, operatively associated with a controller. It is also contemplated that the one or more material layer precursor source 30 may be configured to communicate two or more silicon-containing material layer precursors to the chamber arrangement 14 and remain within the scope of the present disclosure.

In certain examples, the silicon-containing material layer precursor 38 may include a non-halogenated silicon-containing material layer precursor. Non-limiting examples of non-halogenated silicon-containing material layer precursors include silane, disilane, trisilane, and tetrasilane as well as non-halogenated silicon-containing material layer precursors having four or more silicon atoms per molecule. In accordance with certain examples of the present disclosure, the silicon-containing material layer precursor 38 may include a halogenated silicon-containing material layer precursor. Non-limiting examples of halogenated silicon-containing material layer precursors include monochlorosilane, dichlorosilane, and trichlorosilane as well as chlorinated silicon-containing material layer precursors having four or more silicon atoms per molecule. It is also contemplated that the one or more material layer precursor source 30 may include a metal-containing material layer precursor 40. In this respect the one or more material layer precursor source 30 may be configured to provide a flow of a germanium-containing material layer precursor to the chamber arrangement 14, such as germane (GeH₄), and/or a gallium-containing material layer precursor to the chamber arrangement 14, such as gallium trichloride (GaCl₃), and remain within the scope of the present disclosure.

The dopant-containing material layer precursor source 32 is similar to the one or more material layer precursor source 30 and additionally include a dopant-containing material layer precursor 42. The dopant-containing material layer precursor source 32 may be further configured to communicate a flow of the dopant-containing material layer precursor 42 to the chamber arrangement 14, for example via the process fluid 20. In certain examples the dopant-containing material layer precursor 42 may include a p-type dopant, such as boron (B). In accordance with certain example, the dopant-containing material layer precursor 42 may include an n-type dopant, such as phosphorous (P) and/or arsenic (As). As will be appreciated by those of skill in the art in view of the present disclosure, other dopant-containing material layer precursors and/or dopants may be employed and remain within the scope of the present disclosure.

The etchant source 34 is also similar to the one or more material layer precursor source 30, additionally include an etchant 44, and is configured to communicate the etchant 44 to the chamber arrangement 14, for example via the process fluid 20. In certain examples, the etchant 44 may include a halide. Examples of suitable halides include chlorine (Cl), such as in chlorine (Cl₂) gas and hydrochloric (HCl) acid, and fluorine (F), such as through fluorine (F₂) gas and hydrofluoric (HF) acid. In accordance with certain examples, the etchant source 34 may be configured to communicate the etchant 44 to the chamber arrangement 14 independent from the process fluid 20, for example as a purge fluid and/or as a cleaning fluid.

The carrier/diluent fluid source 36 may be coupled to the chamber arrangement 14 and configured to communicate a carrier/diluent fluid 46 to the chamber arrangement 14. In this respect the carrier/diluent fluid source 36 may be configured to co-flow the carrier/diluent fluid 46 to the chamber arrangement 14 with one or more of aforementioned fluids. For example, the carrier/diluent fluid 46 may be co-flowed with the one or more of the silicon-containing material layer precursor 38 to the chamber arrangement 14. The carrier/diluent fluid 46 may be co-flowed with the metal-containing material layer precursor 40 to the chamber arrangement 14. The carrier/diluent fluid 46 may be co-flowed with the etchant 44 to the chamber arrangement 14. And the carrier/diluent fluid 46 may be flowed to the chamber arrangement 14 independent of one or more of the aforementioned fluids, for example as a purge fluid. Non-limiting examples suitable carrier/diluent fluids include hydrogen (H₂) gas and inert gases like nitrogen (N₂) gas and noble gases like argon (Ar), helium (He), and krypton (Kr) as well as mixtures including one or more of the aforementioned carrier/diluent fluids.

The exhaust source 16 is coupled to the process fluid source 12 by the chamber arrangement 14 and is configured to evacuate the chamber arrangement 14. In this respect the exhaust source 16 may include one or more vacuum pump. The one or more vacuum pump may configured to maintain a pressure within the chamber arrangement 14 that is less than 760 Torr, for example between about 760 Torr and 600 Torr, or between about 760 Torr and about 50 Torr, or even between about 760 Torr and about 0.01 Torr. It is also contemplated that the exhaust source 16 may include an abatement device, such as a scrubber and/or a burn box apparatus.

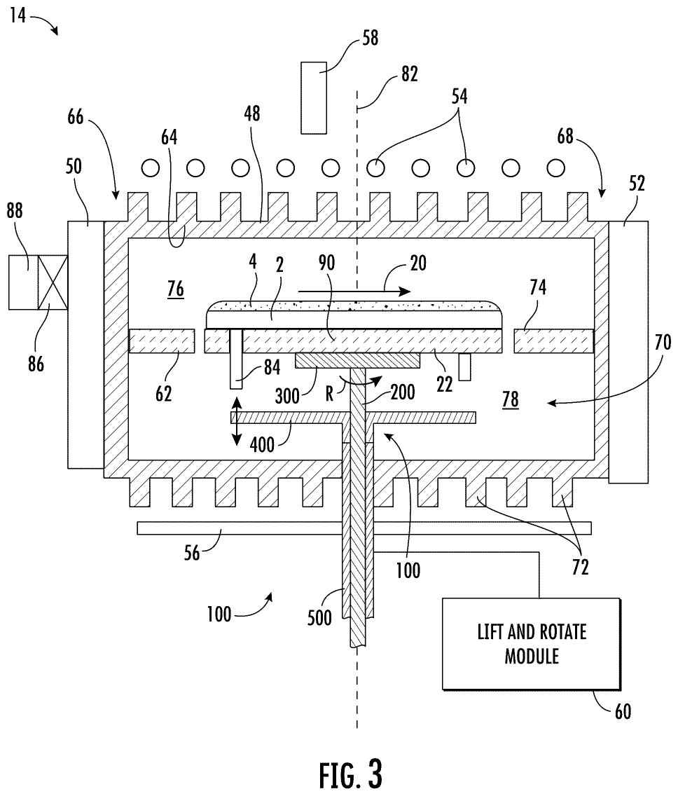

With reference to FIG. 3, the chamber arrangement 14 is shown. In the illustrated example the chamber arrangement 14 has a single-wafer crossflow architecture and includes a chamber body 48, an injection flange 50, and an exhaust flange 52. As shown and described herein the chamber arrangement 14 also includes an upper heater element array 54, a lower heater element array 56, a pyrometer 58, a lift and rotate module 60, a divider 62, and the shaft arrangement 100. Although shown and described herein as having a specific arrangement and including certain elements, it is to be understood and appreciated that the chamber arrangement 14 may have different arrangements, and/or include additional elements or exclude elements shown and described herein and remain within the scope of the present disclosure.

The chamber body 48 is formed from a transparent material 64, e.g., a material transparent to electromagnetic radiation in an infrared waveband and has an injection end 66 and a longitudinally opposite exhaust end 68. The injection flange 50 abuts the injection end 66 of the chamber body 48 and couples the process fluid source 12 (shown in FIG. 1) the chamber body 48. The exhaust flange 52 abuts the exhaust end 68 of the chamber body 48, couples the exhaust source 16 (shown in FIG. 1) to the chamber body 48, and is fluidly coupled to the injection flange 50 by an interior 70 of the chamber body 48. In certain examples, the injection flange 50 may be as shown and described in U.S. Pat. No. 11,053,591 to Ma etal, issued on Jul. 6, 2021, the contents of which is incorporated herein by reference in its entirety. In accordance with certain examples, the exhaust flange 52 may be as shown and described in U.S. Pat. No. 10,612,136 to Sreeram et al, issued on Apr. 7, 2020, the contents of which is incorporated herein by reference in its entirety. It is contemplated that the chamber body 48 may include one or more external rib 72. In such examples the one or more external rib 72 may extend laterally about an exterior surface of the chamber body 48 at a location longitudinally between the injection end 66 and the exhaust end 68 of the chamber body 48. In certain examples, the transparent material 64 forming the chamber body 48 may include (or consist of or consist essentially of) a ceramic material. Non-limiting examples of ceramic materials suitable for forming the chamber body 48 include quartz, fused silica, and sapphire.

The upper heater element array 54 is supported above the chamber body 48 and is configured to communicate heat into the interior 70 of the chamber body 48, for example via operably association with a power supply through via the controller 18 (shown in FIG. 1). In certain examples, the upper heater element array 54 may include a plurality of filament-type heater elements, such as linear and/or bulb filament lamps, supported above the chamber body 48. In accordance with certain examples, the upper heater element array 54 may include a plurality of linear lamps. In such examples the plurality of linear lamps may be supported above the chamber body 48 and extend laterally between sidewalls of the chamber body 48.

It is contemplated that the plurality of linear lamps may further be longitudinally spaced apart from one another above the chamber body 48 between the injection end 66 and the exhaust end 68 of the chamber body 48 in such examples and may be substantially parallel to one another. It is also contemplated that the plurality of linear lamps may extend longitudinally between the injection end 66 and the exhaust end 68 of the chamber body 48, the plurality of linear lamps in such examples laterally spaced apart from one another between laterally opposite sidewalls of the chamber body 48. The lower heater element array 56 may be similar to the upper heater element array 54, additionally be supported below the chamber body 48, and may include a plurality of lower linear lamps. The plurality of lower linear lamps in such examples may be supported below the chamber body, substantially parallel to one another, and substantially orthogonal relative to one or more upper linear lamp of the upper heater element array 54.

The divider 62 may be formed from an opaque material 74, e.g., a material opaque to electromagnetic radiation in an infrared waveband and is supported within the interior 70 of the chamber body 48. It is contemplated that the divider 62 further divide the interior 70 of the chamber body 48 into an upper chamber 76 and a lower chamber 78. It is further contemplated that the divider 62 further define a divider aperture 80 therein, the divider aperture 80 in turn fluidly coupling the upper chamber 76 to the lower chamber 78 of the chamber body 48. In certain examples the opaque material 74 forming the divider 62 may include a ceramic material. In this respect the opaque material 74 may include bulk silicon carbide, bulk graphite coated with silicon carbide, or pyrolytic carbon with a ceramic coating by way of example and not limitation.

The substrate support 22 is arranged within the interior 70 of the chamber body 48. More specifically, the substrate support 22 is arranged within the divider aperture 80 and is supported for rotation R about a rotation axis 82, or more generally an axis defined by the shaft member 200 that is substantially colinear with the rotation axis 82. In this respect the substrate support 22 is carried by the shaft arrangement 100 and operably coupled to the lift and rotate module 60 by the shaft member 200. In the illustrated example a plurality of lift pins 84 are slidably received within the substrate support 22, the plurality of lift pins 84 movable between a retracted and an extended to seat and unseat the substrate 2 from the substrate support 22, the plurality of lift pins 84 in turn cooperating with a gate valve 86 and a substrate transfer robot 88 to seat the substrate 2 subsequent to loading into the chamber body 48 and thereafter unseat and unload the substrate 2 subsequent to deposition of the material layer 4 onto the substrate 2. In certain examples the substrate support 22 may be formed from an opaque material 90, e.g., a material opaque to electromagnetic radiation within an infrared waveband, such bulk graphite coated with silicon carbide. In accordance with certain examples, the substrate support 22 may be coupled to the shaft member 200 and therethrough to the lift and rotate module 60 by a spider member 300. It is also contemplated that the plurality of lift pins 84 may be operably associated with the lift and rotate module 60 through a lift pin actuator 500 and a tube member 400. In this respect it is contemplated that lift pin actuator 500 and the tube member 400 may be as shown and described in U.S. Patent Application Publication No. 2023/0116427 A1 to Su et al., published on Apr. 13, 2023, the contents of which is incorporated herein by reference in its entirety.

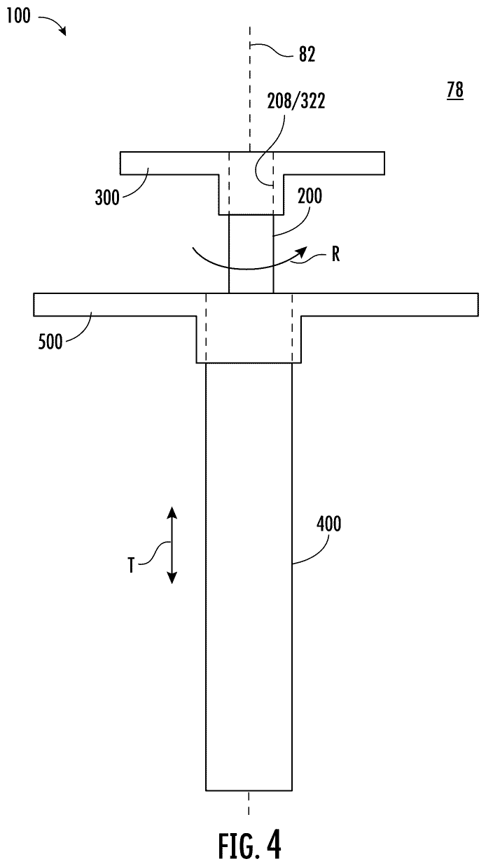

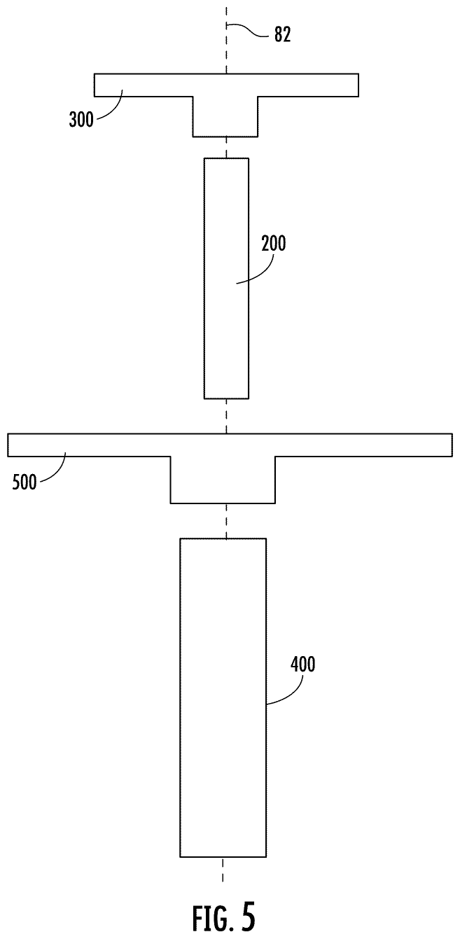

With reference to FIGS. 4 and 5, the shaft arrangement 100 is shown. The shaft member 200 is arranged along the rotation axis 82 and seats thereon the spider member 300. The shaft member 200 is further supported for rotation R about the rotation axis 82 relative to the chamber body 48 (shown in FIG. 3) and in this respect may be operably associated with the lift and rotate module 60 (shown in FIG. 3). The spider member 300 is seated on the shaft member 200, is fixed in rotation R about the rotation axis 82 relative to the shaft member 200 and is configured to couple the substrate support 22 (shown in FIG. 1). The lift pin actuator 500 extends about the rotation axis R and shaft member 200, is fixed in rotation relative to the chamber body 48 and translatable along the rotation axis 82 relative to the shaft member 200 and the chamber body 48, and is seated on the tube member 400, The tube member 400 is arranged along the rotation axis 82, extends about the shaft member 200, and seats thereon the lift pin actuator 500. The tube member 400 is further supported for translation T along the rotation axis 82 and may also be operably associated with the lift and rotate module 60 to actuate the plurality of lift pins 84 (shown in FIG. 3).

The lift pin actuator 500 is fixed in rotation R relative to the tube member 400 about the rotation axis 82 and is configured to drive the plurality of lift pins 84 (shown in FIG. 3) through the substrate support 22 during seating and unseating of substrate 2 (shown in FIG. 1) from the substrate support 22. In this respect it is contemplated that the shaft member 200 be supported for rotation R about the rotation axis 82 and be axially fixed along the rotation axis 82 relative to the chamber body 48 (shown in FIG. 3). In further respect, it is also contemplated that the tube member 400 be axially free for translation along the rotation axis 82 and fixed in rotation R about the rotation axis 82 relative to the chamber body 48. As shown in FIG. 5, it is contemplated that the tube member 400 be arranged along the rotation axis 82 and supported for translation along the rotation axis 82 and that the lift pin actuator 500 be seated on the tube member 400 for translation with the push tube along the rotation axis 82. The shaft member 200 may be arranged along the rotation axis 82 within (at least partially) the tube member 400 and supported for rotation about the rotation axis 82. The spider member 300 may be seated on the shaft member 200 and fixed in rotation R about the rotation axis 82 relative to shaft member 200.

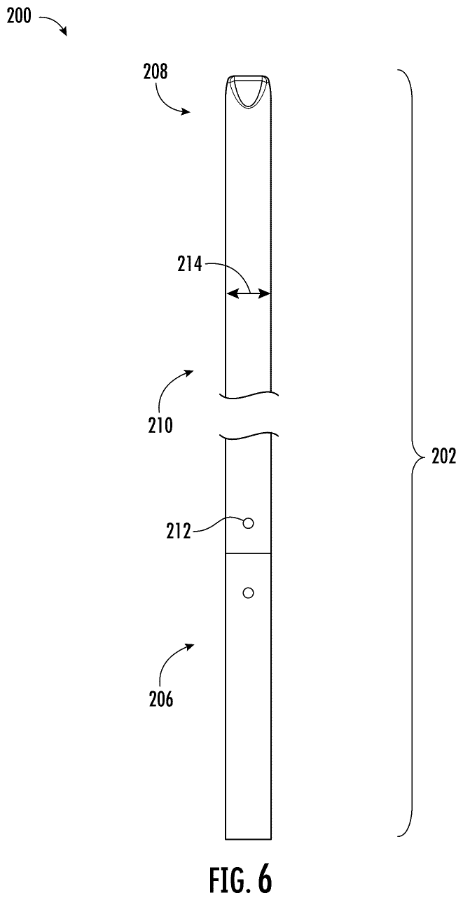

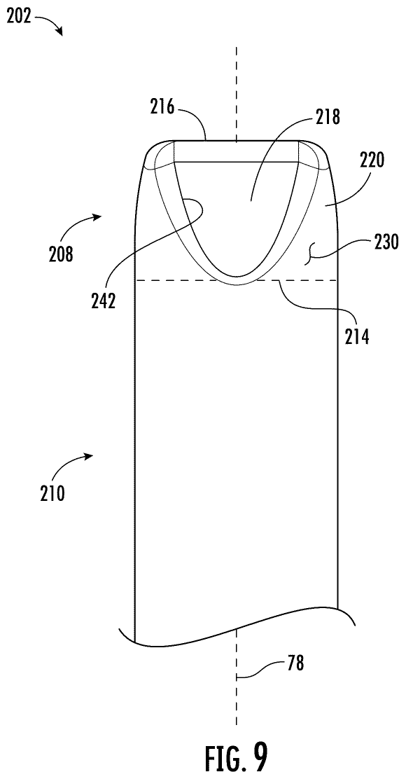

With reference to FIGS. 6-10, the shaft member 200 is shown according to an example of the disclosure. As shown in FIG. 6, the shaft member 200 is configured and adapted to seat thereon the spider member 300 (shown in FIG. 3) and includes a shaft member body 202. The shaft member body 202 may be formed from a transparent material 204 (shown in FIG. 9), e.g., a material transparent to electromagnetic radiation in an infrared waveband and have a drive end 206 and an axially opposite seat end 208 separated from one another by an intermediate segment 210. The drive end 206 may be configured for engagement by the lift and rotate module 60 (shown in FIG. 3), for example using a fixation feature 212, which may include one or more of a through-hole, an axial slot, and a spline feature.

The intermediate segment 210 of the shaft member body 202 extends from the drive end 206 of the shaft member body 202 and along the rotation axis 82. It is contemplated that the intermediate segment 210 further couple the seat end 208 of the shaft member body 202 to the drive end 206 of the shaft member body 202, and that the shaft member body 202 define a shaft member diameter 214. In certain examples, the shaft member diameter 214 may be substantially continuous along an axial length of the intermediate segment 210 of the shaft member body 202. In this respect the shaft member diameter 214 may be substantially continuous along an axial length of the shaft member body 202 between the fixation feature 212 and the seat end 208 of the shaft member body 202. In accordance with certain examples, the shaft member diameter 214 may be continuous along both the intermediate segment 210 of the shaft member body 202 and the drive end 206 of the shaft member body 202.

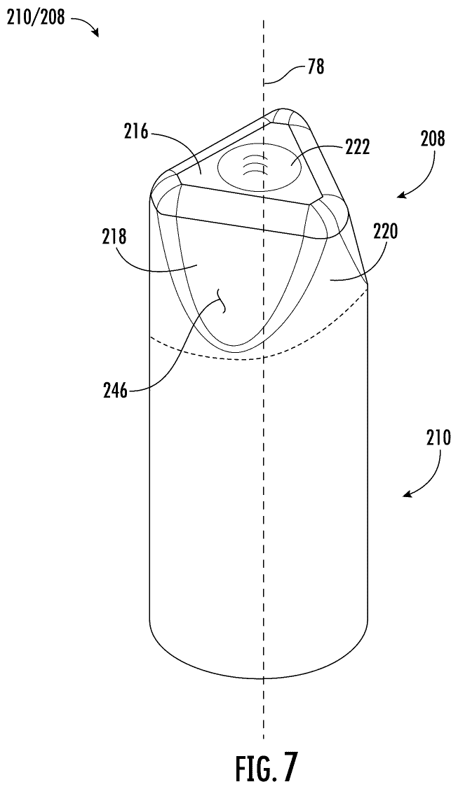

As shown in FIG. 7, the seat end 208 of the shaft member body 202 may be separated from the drive end 206 (shown in FIG. 6) by the intermediate segment 210 the shaft member body 202. In this respect the furthest axial extent of the shaft member diameter 214 may demarcate the axial end of the intermediate segment 210 and beginning of the seat end 208 of the shaft member body 202. It is contemplated that the seat end 208 of the shaft member body 202 further have a seat end face 216, a plurality of oblique facets 218, and a plurality of wedge facets 220. The seat end face 216 may define a planar shape. The seat end face 216 may be orthogonal relative to the rotation axis 82. The seat end face 216 may further have a generally triangular shape.

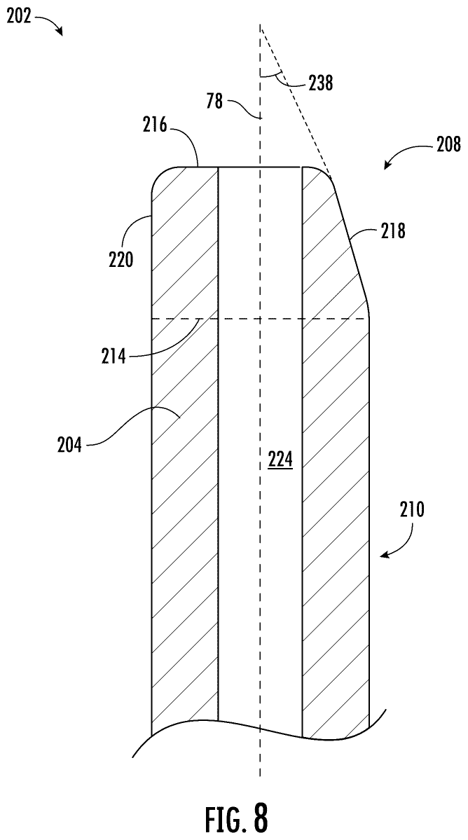

As shown in FIG. 8, the seat end face 216 may define therein a seat end face aperture 222. The seat end face aperture 222 may extend about the rotation axis 82. The seat end face aperture 222 may further couple a through-bore 224 defined within the shaft member body 202 to the environment external to shaft member body 202. The through-bore 224 may extend from the seat end face aperture 222 through the seat end 208 of the shaft member body 202 and along the rotation axis 82. In certain examples of the present disclosure the through-bore 224 may extend axially through intermediate segment 210 the shaft member body 202. In accordance with certain examples, the through-bore 224 may further extend through the drive end 206 of the shaft member body 202, the through-bore being in further communication with the external environment outside of the shaft member body 202 through a seat end face aperture 222 defined within the seat end face 216 to a drive end face aperture defined within an end face of the drive end 206 of the shaft member body 202. In such examples the through-bore 224 may be configured to receive therein a thermocouple, for example to acquire temperature measurements from an underside of the substrate support 22 (shown in FIG. 3) to control temperature of the substrate 2 (shown in FIG. 1) during deposition of the material layer 4 (shown in FIG. 1) onto the substrate 2. Examples of suitable thermocouples include thermocouples shown and described in U.S. Pat. No. 8,262,287 to Darabnia et al., issued on Sep. 11, 2012, the contents of which are incorporated herein by reference in its entirety.

As shown in FIG. 9, the oblique facet 218 is configured to carry the spider member 300 (shown in 3) on the seat end 208 of the shaft member body 202. In this respect it is contemplated that oblique facet 218 define a planar surface 240 that is angled relative to the rotation axis 82 at an oblique facet angle 238. The planar surface 240 may further be bounded by a parabolic periphery 242, the parabolic periphery 242 extending between (or from) the seat end face 216 to the intermediate segment 210 of the shaft member body 202. It is contemplated that the parabolic periphery 242 open in a direction toward the seat end face 216 of the seat end 208 of the shaft member body 202, a vertex 244 of the parabolic periphery 242 proximate the intermediate segment 210 of the shaft member body 202. In certain examples the oblique facet angle 238 may be between about 5 degrees and about 40 degrees, such as between about 5 degrees and about 30 degrees, or between about 5 degrees and about 25 degrees, or even between about 10 degrees and about 20 degrees. The oblique facet 218 may be angled relative to the axis at an oblique facet angle that is between about 5 degrees and about 15 degrees, or that is between about 8 degrees and about 12 degrees, or is about 10 degrees in certain examples. Advantageously, oblique facet angles within these ranges can limit tendency of the spider member 300 (shown in FIG. 3) to become fixed to the seat end 208 of the shaft member body 202 due to thermal cycling of the shaft arrangement 100, facilitating removal of the spider member 300 from the shaft member 200, such as during servicing of the semiconductor processing system 10 (shown in FIG. 1).

In certain examples, the oblique facet 218 may join the seat end face 216 at an oblique facet-to-seat end face chamfer 232. The oblique facet-to-seat end face chamfer 232 may extend between the planar surface 240 and the seat end face 216, such as at a blended interface. In accordance with certain examples, the oblique facet 218 may join wedge facets 220 circumferentially adjacent to the oblique facet 218 at an oblique facet-to-wedge facet chamfer 234. In such examples the oblique facet-to-wedge facet chamfer 234 may extend continuously along the parabolic periphery 242 bounding the planar surface 240 of the oblique facet 218. Advantageously, forming the oblique facet 218 the oblique facet-to-seat end face chamfer 232 and the oblique facet-to-wedge facet chamfer 234 may cut such that clearance exists between the spider member 300 and respective chamfer, forcing the spider member 300 to seat on the oblique facet 218 of the seat end 208 of the shaft member body 202.

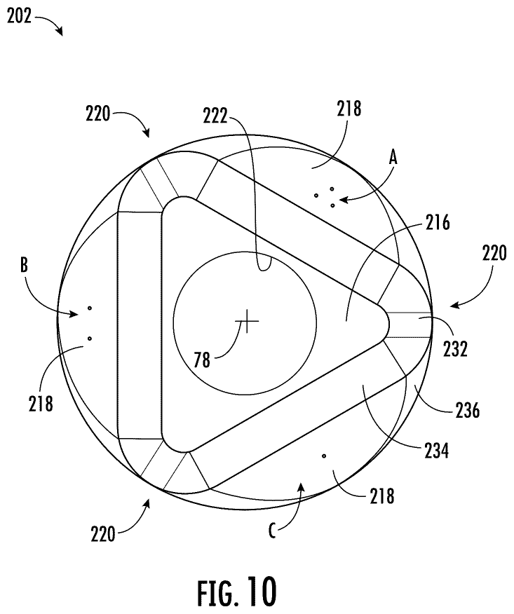

As shown in FIG. 10, the oblique facet 218 facet may be one of three (3) oblique facets 218 defined on the seat end 208 of the shaft member body 202. The three (3) oblique facets 218 may be circumferentially separated from one another by about 120 degrees about the rotation axis 82. The three (3) oblique facets 218 may be separated by one another by three (3) wedge facets 220 in such examples, circumferentially adjacent oblique facets 218 separated by individual wedge facets 220 of the three (3) wedge facets 220. Advantageously, examples including three wedge facets 220 enable locating the spider member 300 in a 3-2-1 location scheme ABC (shown in FIG. 10) wherein the spider member 300 is constrained in six degrees of freedom, limiting (or eliminating) backlash within the shaft arrangement 100. To further advantage, employment of the three (3) oblique facets 218 enables locating the spider member 300 while simplifying fabrication of the shaft member 200 as the oblique facets 218 may be formed using a comparatively simple grinding operation-and not a more complex turning process to form a cone structure on the shaft member 200. Although shown and described herein as having three (3) oblique facets 218, it is to be understood and appreciated that the seat end 208 of the shaft member body 202 may have fewer or additional oblique facets 218 and remain within the scope of the present disclosure.

The wedge facets 220 are configured rotational fix the spider member 300 relative to the shaft member 200 for rotating the substrate support 22 (shown in FIG. 1) using the lift and rotate module 60 (shown in FIG. 3) through the shaft member 200 and the spider member 300. In this respect, and as shown in FIG. 8, that the wedge facet 220 may extend axially from the seat end face 216 and toward the intermediate segment 210 of the shaft member body 202. The wedge facet 220 may further terminate axially at the shaft member diameter 214. The wedge facet 220 may be circumferentially offset from the oblique by about 180 degrees. As shown in FIG. 9, the wedge facet 220 may define a wedge face 230 having a generally triangular shape (when viewed radially) with an arcuate profile (when viewed axially) corresponding to a circumference of the intermediate segment 210 of the shaft member body 202. In certain examples of the present disclosure the wedge facet 220 may join the seat end face 216 at a wedge facet-to-seat end face chamfer 236. As will be appreciated by those of skill in the art in view of the present disclosure, forming the seat end 208 of the shaft member body 202 with the wedge facet-to-seat end face chamfer 236 may improve reliability of the shaft arrangement 100 (shown in FIG. 1), for example by limiting (or eliminating) risk that the spider member 300 chip the shaft member 200 during installation and/or removal of the spider member 300 from the shaft member 200 in examples where the shaft member body 202 is formed from a relatively brittle material, such as a ceramic material like quartz.

With continuing reference to FIG. 10, it is contemplated that the wedge facet 220 may be one of a plurality of wedge facets 220 distributed circumferentially about the seat end 208 of the shaft member body 202. In this respect it is contemplated that the wedge facet 220 may be one of a plurality of wedge facets 220 each circumferentially separating circumferentially pairs of oblique facets 218, the plurality of wedge facets 220 and the plurality of oblique facets 218 distributed circumferentially about the rotation axis 82 on the seat end 208 of the shaft member body 202. In the illustrated example the wedge facet 220 is one of three (3) wedge facets 220 distributed circumferentially about the rotation axis 82 on the seat end 208 of the shaft member body 202, each of the plurality of wedge facets 220 separating adjacent pairs of three (3) oblique facets 218. Advantageously, forming the seat end 208 of the shaft member body 202 with three (3) wedge facets 220 may simplify fabrication of the shaft member 200 by limiting (or eliminating) the need to define a conical surface on the seat end 208 of the shaft member body 202 with a torque transfer structure. Instead, the seat end 208 of the shaft member body 202 may transfer torque using a tangential components of force exerted by the one or more oblique facet 218 against the spider member body 302, eliminating the need to define a dedicated torque transfer feature on the seat end 208 of the shaft member body 202.

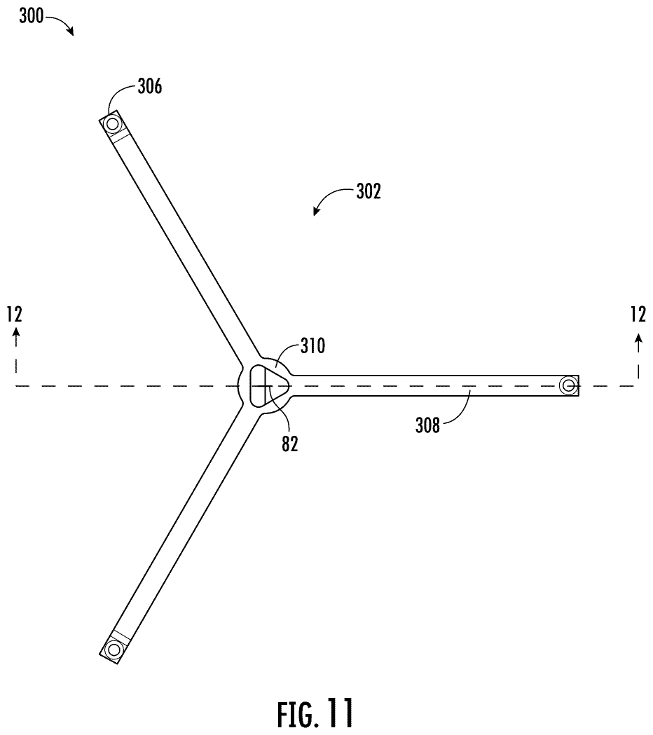

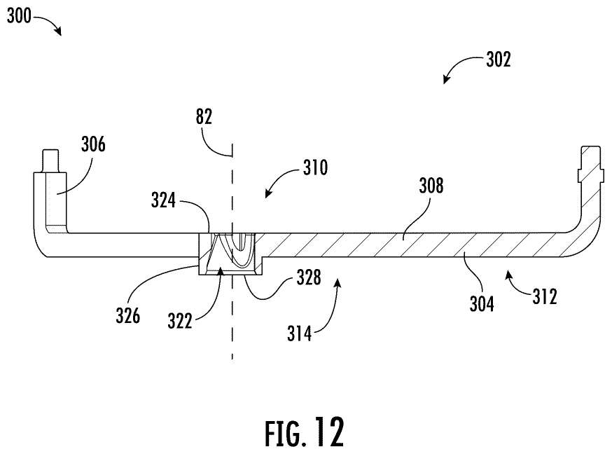

Referring to FIGS. 11-15, the spider member 300 is shown. As shown in FIG. 11, the spider member 300 is configured and adapted to couple the substrate support 22 (shown in FIG. 3) to the shaft member 200 and in this respect includes a spider member body 302. The spider member body 302 may be formed from a transparent material 304 (shown in FIG. 12), e.g., a material transparent to electromagnetic radiation within an infrared waveband, which may be same as the transparent material 204 forming the shaft member body 202. It is contemplated that the spider member body 302 have one or more seat portion 306, one or more arm portion 308, and a hub portion 310. The one or more seat portion 306 is configured to be slidably received within a corresponding recess defined within a lower surface of the substrate support 22 and is radially separated from the hub portion 310 by the arm portion 308 of the spider member body 302. In certain examples of the present disclosure the one or more seat portion 306 may extend axially along the rotation axis 82 and in a direction axially opposite the hub portion 310 of the spider member body 302. In accordance with certain examples, the one or more arm portion 306 may be substantially parallel to the rotation axis 82. It is also contemplated that the one or more arm portion 306 may be oblique or substantially orthogonal relative to the one or more arm portion 308 of the spider member body 302. As will be appreciated by those of skill in the art in view of the present disclosure, forming the spider member body 302 such that the one or more arm portion 306 is substantially orthogonal relative to the one or more arm portion 308 may simplify fabrication of the spider member 300.

It is contemplated that the one or more seat portion 306 may be one of a plurality of seat portions 306. In this respect, and as shown in FIG. 11, the one or more seat portion 306 may be one of three (3) seat portions 306 distributed about the hub portion 110 and the rotation axis 82. In further respect, each of the plurality of seat portions 306 may be offset from circumferentially adjacent seat portions 306 by a separate angle, which may be about 120 degrees in certain examples of the present disclosure. Although shown and described herein as having three (3) seat portions 306, it is to be understood and appreciated by spider member body 302 may have fewer or additional seat portions 306 and remain within the scope of the present disclosure.

As shown in FIG. 12, the arm portion 308 of spider member body 302 couples the seat portion 306 of the spider member body 302 to the hub portion 310 of the spider member body 302. It is contemplated that the arm portion 308 have a radially outer segment 312 and a radially inner segment 314. The seat portion 306 may protrude from the radially outer segment 312 of the arm portion 308 of the spider member body 302 along the rotation axis 82 and be coupled therethrough to the hub portion 310 of the spider member body 302. The radially inner segment 314 of the arm portion 308 of the spider member body 302 in turn may couple the radially outer segment 312 to the hub portion 310 of the spider member body 302. The radially inner segment 314 may further protrude radially from an exterior peripheral surface 326 of the hub portion 310 of the spider member body 302. In certain examples of the present disclosure the one or more arm portion 308 may be one of a plurality of arm portions 308 of the spider member body 302, for example one of three (3) arm portions 308 of the spider member body 302. As will be appreciated by those of skill in the art in view of the present disclosure the spider member body 302 may have fewer or additional arm portions 308 and remain within the scope of the present disclosure.

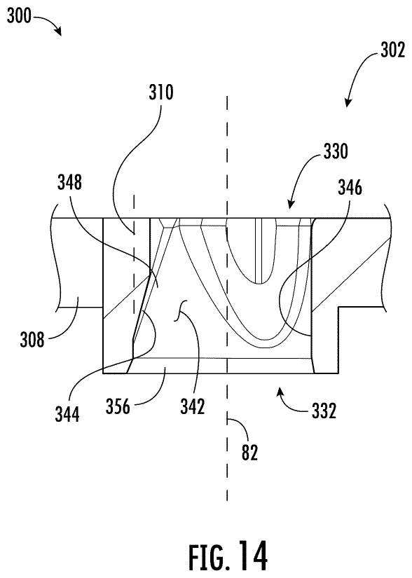

The hub portion 310 of the spider member body 302 is configured and adapted to seat on the seat end 208 of the shaft member 200. In this respect it is contemplated that the hub portion 310 define an internal seating socket 322 and have an upper surface 324, an exterior peripheral surface 326, a lower surface 328. The upper surface 324 is arranged along the rotation axis 82 and defines an upper aperture 330. The upper surface 324 is further separated from the lower surface 328 by an exterior peripheral surface 326, extends about the upper aperture 330 and about the rotation axis 82, and is generally annular in shape. The exterior peripheral surface 326 extends axially from the upper surface 324 along the rotation axis 82, joins the radially inner segment 314 of the arm portion 308 of the spider member body 302 at a chamfer or fillet, and may be generally cylindrical in shape. The lower surface 328 extends about the rotation axis 82 and defines therein a lower aperture 332 (shown in FIG. 14). It is contemplated that either (or both) the upper surface 324 and the lower surface 328 may be substantially orthogonal relative to the rotation axis 82 and/or the lone or more seat portion 306. It is also contemplated that the exterior peripheral surface 326 may be substantially parallel to the rotation axis 82. It is further contemplated that the one or more arm portion 308 may be substantially orthogonal relative to the exterior peripheral surface 326 of the hub portion 310 of the spider member body 302.

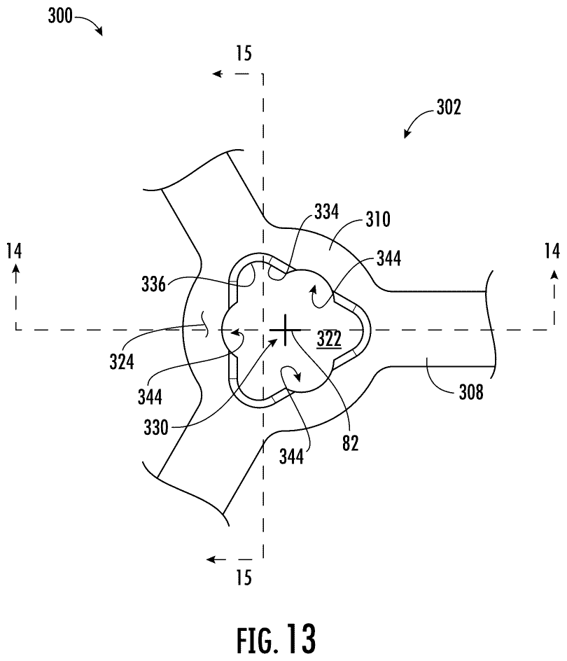

As shown in FIG. 13, the upper aperture 330 defined within the upper surface 324 of the hub portion 310 of the spider member body 302 be bounded by a plurality of linear segments 334 and a plurality of arcuate segments 336. The plurality of arcuate segments 336 may be distributed circumferentially about the rotation axis 82. The plurality of arcuate segments 336 may further be spaced apart from one another by respect linear segments 334 bounding the upper aperture 330. The plurality of arcuate segments 336 may additionally correspond in number and curvature to the plurality of wedge facets 220 (shown in FIG. 7) of the seat end 208 of the shaft member body 202 (shown in FIG. 6), the seat end face 216 (shown in FIG. 7) of the shaft member body 202 occupying the upper aperture 330 (at least in part) when the spider member 300 is seated on the shaft member 200 (shown in FIG. 1). The plurality of linear segments 334 may be distributed about the rotation axis 82, tangent to a circumference extending about the rotation axis 82, and/or correspond in length to widths of the oblique facets 218 (shown in FIG. 7).

In certain examples, the one or more linear segment 334 may be interrupted by an intermediate arcuate segment 338 extending radially outward from the rotation axis 82, the hub portion 310 thereby locating on the shaft member body 202 at respective oblique facet-to-wedge facet chamfers 234 defined between plurality of wedge facets 220 and the plurality of oblique facets 218 defined by the seat end 208 of the shaft member body 202. In the illustrated example the upper aperture 330 is bounded by three (3) linear segments 334 and three (3) arcuate segments 336-each of the arcuate segments 336 interrupted (e.g., bisected) by a singular intermediate arcuate segment 338. As will be appreciated by those of skill in the art in view of the present disclosure, the upper aperture 330 may be bounded by fewer or additional linear segments 334, and/or arcuate segments 336, and remain within the scope of the present disclosure.

As shown in FIG. 14, the lower aperture 332 of the hub portion 310 is defined within the lower surface 328 of the hub portion 310. The lower aperture 332 further extends circumferentially about the rotation axis 82 at a location radially inward of the exterior peripheral surface 326 of the hub portion 310 of the spider member body 302, is coupled to the upper aperture 330 by the seating socket 322 and may be generally circular in shape. It is contemplated that the upper aperture 330 may be bounded by lower surface-to-seating socket chamfer 356. As will be appreciated by those of skill in the art in view of the present disclosure, forming the spider member body 302 with the lower surface-to-seating socket chamfer 356 may simplify assembly of the shaft arrangement 100 (shown in FIG. 1), for example by making the assembly process tolerant of misregistration of the spider member 300 to the shaft member 200 (shown in FIG. 3) during seating of the spider member 300 onto the shaft member 200. In certain examples, the lower aperture 332 may have a lower aperture diameter 340 greater than the shaft member diameter 214 (shown in FIG. 8) defined by the intermediate segment 210 (shown in FIG. 6) of the shaft member body 202 (shown in FIG. 6), also simplifying assembly of the shaft arrangement 100.

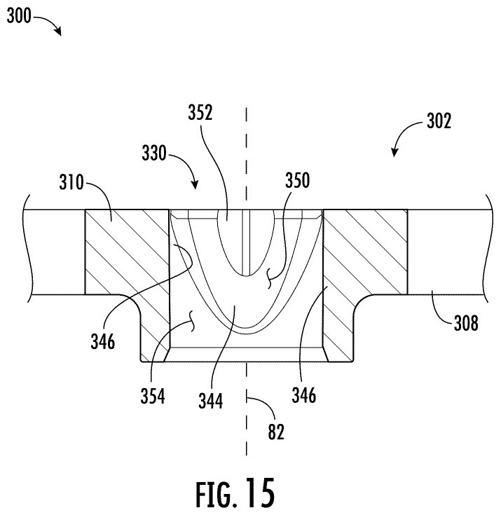

As shown in FIG. 15, the seating socket 322 is configured and adapted to for location on the oblique facet 218 (shown in FIG. 7) of the seat end 208 (shown in FIG. 6) of the shaft member body 202 (shown in FIG. 6) and rotation according to force exerted on an interior surface 342 of the hub portion 310 by the oblique facet 218 of the shaft member body 202. In this respect it is contemplated that the interior surface 342 of the hub portion 310 define one or more oblique face 344 and one or more wedge slot 346. The one or more oblique face 344 may further be conjugate (e.g., operating as if joined by the aforementioned 3-2-1 location scheme of the spider member 300 on the shaft member 200) to the one or more oblique facet 218 defined by the seat end 208 of the shaft member body 202. For example, the one or more oblique face 344 may slope toward the upper aperture 330 at an oblique face angle 348 that is substantially equivalent to the oblique facet angle 238 of the one or more oblique facet 218 of the seat end 208 of the shaft member body 202. The one or more oblique face 344 may have an oblique face area 350 that is substantially equivalent to an oblique facet area 246 (shown in FIG. 7) of the one or more oblique facet 218. The one or more oblique face 344 may further couple the lower aperture 332 to one of the plurality of linear segments 334 (shown in FIG. 13) bounding the upper aperture 330.

In certain examples a relief recess 352 may be defined within the one or more oblique face 344. In such examples the relief recess 352 may extend from the intermediate arcuate segment 338 (shown in FIG. 13) bisecting the linear segment 334 (shown in FIG. 13) to a location along the one or more oblique face 344 axially spaced apart from the lower aperture 332. Advantageously, defining the relief recess 352 within the one or more oblique face 344 may circumferentially space contact points of the 3 and 2 planes of the 3-2-1-location scheme of the spider member 300 on the shaft member 200 when the spider member 300 is seated on the seat end 208 of the shaft member 200. In the illustrated example, and as shown in FIG. 13, the interior surface 342 of the hub portion 310 defines three (3) oblique faces 344. As will be appreciated by those of skill in the art in view of the present disclosure, the seating socket 322 may be bounded by or additional oblique faces 344 and remain within the scope of the present disclosure.

With continuing reference to FIG. 15, the one or more wedge slot 346 is configured and adapted to slidably receive therein the one or more wedge facet 220 (shown in FIG. 7) defined by the seat end 208 (shown in FIG. 6) of the shaft member body 202 (shown in FIG. 6). In this respect the one or more wedge slot 346 may be circumferentially adjacent to the one or more oblique face 344. The one or more wedge slot 346 may further be conjugate to the one or more wedge facet 220. In this respect the one or more wedge slot 346 may be substantially parallel to the exterior peripheral surface 326 of the hub portion 310 of the spider member body 302. In further respect, the one or more wedge slot 346 may further have a wedge slot area 354 that is substantially equivalent to that of the wedge face 230 defined by the one or more wedge facet 220.

In certain examples the one or more wedge slot 346 may extend axially between the lower aperture 332 defined within the lower surface 328 of the hub portion 310 and a respective one of the plurality of arcuate segments 336 bounding the upper aperture 330 defined within the upper surface 324 of the hub portion 310 of the spider member body 302. In accordance with certain examples, the number of wedge slots 346 defined within the seating socket 322 may match the number of wedge facets 220 (shown in FIG. 7) defined by the seat end 208 (shown in FIG. 6) of the shaft member body 202 (shown in FIG. 6), the wedge facets 220 of the shaft member body 202 thereby cooperating with the wedge slots 346 defined within the hub portion 310 to fix the shaft member 200 in rotation R relative to the spider member 300 about the rotation axis 82. In the illustrated example the interior surface 342 bounding the seating socket 322 defines three (3) wedge slots 346. As will be appreciated by those of skill in the art in view of the present disclosure, the interior surface 342 of the hub portion 310 of the spider member body 302 may define fewer or additional wedge slots 346 than shown and described herein and remain within the scope of the present disclosure.

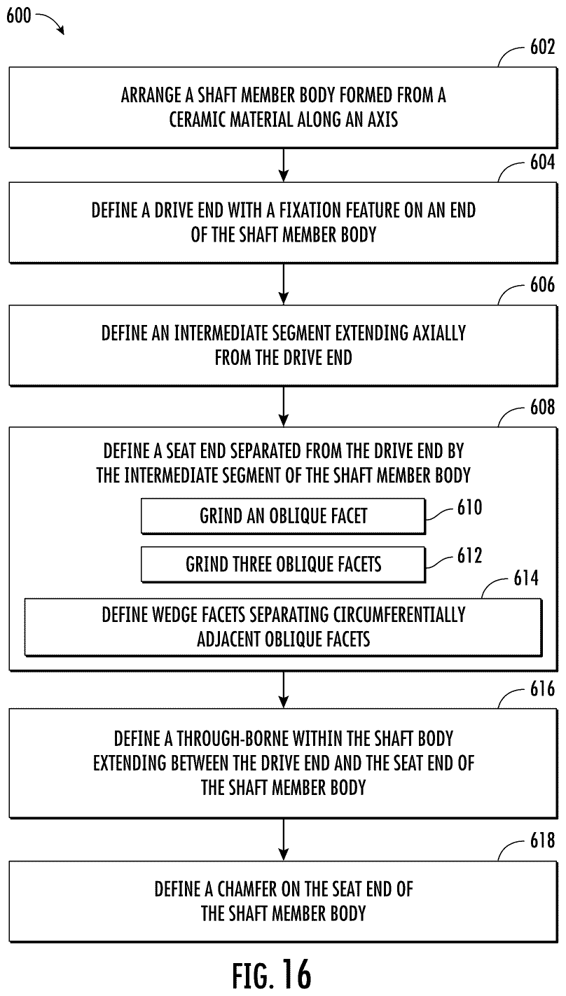

With reference to FIG. 16, a method 600 of making a shaft member, e.g., the shaft member 200 (shown in FIG. 1), is shown. The method 600 includes arranging a shaft member body formed from a ceramic material along an axis, e.g., arranging the shaft member body 202 (shown in FIG. 6) formed from the transparent material 204 (shown in FIG. 8) along the rotation axis 82 (shown in FIG. 3), as shown with box 602. The method 600 also includes defining a drive end having a fixation feature on an end of the shaft member body, e.g., defining the fixation feature 212 (shown in FIG. 6) in the drive end 206 (shown in FIG. 6) in the shaft member body, as shown with box 604. The method 600 further includes defining an intermediate segment extending axially from the drive end of the shaft member and a seat end separated axially from the drive end on an axially opposite end of the shaft member body, e.g., the intermediate segment 210 (shown in FIG. 6) and the seat end 208 (shown in FIG. 6), as shown with box 606 and box 608. It is contemplated that the seat end be defined by griding one or more oblique facet in the end of the shaft member body axially opposite the drive end of the shaft member body, e.g., the one or more oblique facet 218 (shown in FIG. 7), as shown with box 610.

In certain example of the present disclosure defining 610 the one or more oblique facet may include grinding three (3) oblique facets into the seat end of the shaft member body, as shown with box 612. In accordance with certain examples, defining 610 the one or more oblique facet may include defining one or more wedge facet separating circumferentially adjacent oblique facets, as shown with box 614. It is contemplated that, in accordance with certain examples, a through-bore may be defined within the shaft member body extending between the drive end and the seat end of the shaft member body, e.g., the through-bore 224 (shown in FIG. 8), as shown with box 616. It is also contemplated the method 600 may additionally include defining one or more chamfer on the seat end of the shaft member body, e.g., one or more of the wedge facet-to-seat end face chamfer 236 (shown in FIG. 10), the oblique facet-to-seat end face chamfer 232 (shown in FIG. 10, and/or the oblique facet-to-wedge facet chamfer 234 (shown in FIG. 10), as shown with box 618. In such examples one more of the chamfers may extend axially from a seat end face defined on the seat end of the shaft member body and substantially orthogonal relative to the axis using a sawing or cutting operation, e.g., the seat end face 216 (shown in FIG. 7), as also shown with box 618.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A shaft member, comprising:
a shaft member body arranged along an axis and having:
a drive end defining a fixation feature therein;
an intermediate segment extending from the drive end of the shaft member body; and a seat end axially separated from the drive end of the shaft member body by the intermediate segment of the shaft member body,
wherein the seat end has one or more oblique facet configured to axially locate a spider member on the shaft member body.

2. The shaft member of claim 1, wherein the shaft member body is formed from a ceramic material.

3. The shaft member of claim 1, wherein the shaft member has a seat end face that is substantially orthogonal relative to the axis.

4. The shaft member of claim 3, wherein the shaft member defines therein a through-bore extending axially from a seat end face aperture defined within the seat end face of shaft member body to the drive end of the shaft member body.

5. The shaft member of claim 3, wherein the seat end of the shaft member body defines an oblique facet-to-seat end face chamfer coupling the one or more oblique facet to the seat end face of the shaft member body.

6. The shaft member of claim 1, wherein the oblique facet is angled relative to the axis at an oblique facet angle that is between about 5 degrees and about 40 degrees, or between about 5 degrees and about 30 degrees, or between about 5 degrees and about 25 degrees, or between about 10 degrees and about 20 degrees, or even that is between about 8 degrees and about 12 degrees.

7. The shaft member of claim 1, wherein the one or more oblique facet is one of three (3) oblique facets defined on the seat end of the shaft member body.

8. The shaft member of claim 1, wherein the seat end of the shaft member body defines one or more wedge facet circumferentially offset from the one or more oblique facet.

9. The shaft member of claim 8, wherein the one more wedge facet is substantially parallel to the intermediate segment of the shaft member body.

10. The shaft member of claim 8, wherein the one or more wedge facet is one of three (3) wedge facets defined by the seat end of the shaft member body, wherein the one or more oblique facet is one of three (3) oblique facets defined by the seat end of the shaft member body, and wherein each of the wedge facets separate circumferentially adjacent oblique facets defined on the seat end of the shaft member body.

11. The shaft member of claim 8, wherein the seat end defines a wedge facet-to-oblique facet chamfer coupling the one or more wedge facet to the one or more oblique facet defined by the seat end of the shaft member body.

12. The shaft member of claim 8, wherein the one or more wedge portion defines a wedge facet-to-seat end face chamfer coupling the one or more wedge facet to the seat end face of the seat end of the shaft member body.

13. A shaft arrangement, comprising:
a shaft member as recited in claim 1, wherein the shaft member body defines one or more wedge portion circumferentially offset from the one or more oblique facet; and
a spider member including a spider member body having:
a hub portion extending about the axis and defining a seating socket therein;
one or more arm portion extending radially from the hub portion; and
one or more seat portion extending axially from the arm portion and radially separated from the hub portion by the arm portion of the spider member body,
wherein the shaft end of the spider member body is received within the seating socket defined within the hub portion of the spider member body.

14. The shaft arrangement of claim 13, wherein the seating socket is bounded by one or more oblique face, and wherein the one or more oblique face is conjugate to the one or more oblique facet defined by the seat end of the shaft member body.

15. The shaft arrangement of claim 13, wherein the seating socket is bounded by three (3) oblique faces distributed circumferentially about the rotation axis, and wherein each of the three (3) oblique facets are conjugate to a respective one (1) of three (3) oblique facets defined by the seat end of the shaft member body.

16. The shaft arrangement of claim 13, wherein the seating socket is bounded by one or more wedge face, and wherein the one or more wedge face is conjugate to the one or more wedge facet defined by the seat end of the shaft member body.

17. The shaft arrangement of claim 13, wherein the seating socket is bounded by three (3) wedge faces distributed circumferentially about the rotation axis, and wherein each of the three (3) wedge facets are conjugate to a respective one (1) of three (3) wedge facets defined by the seat end of the shaft member body.

18. The shaft arrangement of claim 13, wherein the hub portion has an upper surface defining an upper aperture and a lower surface defining lower aperture, the lower aperture coupled to the upper aperture by the seating socket and having a generally circular shape, the upper aperture bounded by a plurality linear segments and linear segments.

19. The shaft arrangement of claim 18, wherein the one or more oblique face defines a relief recess therein extending from the upper aperture to a location axially intermediate the upper aperture and the lower aperture of the hub portion of the spider member body.

20. The shaft arrangement of claim 13, further comprising:
a tube member arranged along the rotation axis and extending about the shaft member;
a lift pin actuator seated on the tube member and extending about the shaft member; and
wherein the spider member is axially separated from the tube member along the axis by the lift pin actuator.

21. The shaft arrangement of claim 13, further comprising a substrate support seated on the spider member and coupled therethrough to the shaft member.

22. A semiconductor processing system, comprising:
a process fluid source including a material layer precursor;
a chamber arrangement including a shaft member as recited in claim 1, the shaft member coupling a substrate support to a lift and rotate module;
an exhaust source coupled to the chamber arrangement; and
a controller operatively coupled to the chamber arrangement and configured to deposit a material layer onto a substrate seated on the substrate support using a flow of the material layer precursor communicated by the process fluid source.

23. A method of making a shaft member, comprising:
arranging a shaft member body formed from a ceramic material along an axis;
defining a fixation feature on a drive end of the shaft member body;
defining an intermediate segment extending axially from the drive end of the shaft member body; and
defining a seat end axially separated from the drive end of the shaft member body by grinding one or more oblique facet into the shaft member body configured to axially locate a spider member on the shaft member body in a 3-2-1 locating scheme.
